(19) United States
(12) Patent Application Publication
(10) Pub. No.: US 2006/0284298 A1
(43) Pub. Date: Dec. 21, 2006

(54) Chip stack package having same length bonding leads

(76) Inventors: Jae Myun Kim, Kyoungki-do (KR); Sung Ho Kim, Seoul (KR); Chan Ki Hwang, Seoul (KR)

Correspondence Address: LADAS & PARRY LLP, 224 SOUTH MICHIGAN AVENUE, SUITE 1600, CHICAGO, IL, 60604, US

(21) Appl. No.: 11/302,622

(22) Filed: Dec. 14, 2005

(30) Foreign Application Priority Data
Jun. 15, 2005 (KR) 10-2005-0051434

(51) Int. Cl. H01L 23/02

(52) U.S. Cl. 257/686

(57) ABSTRACT

A chip stack package has semiconductor chips connected to the substrate by the same signal pathway lengths to prevent malfunction of the semiconductor chips. In the chip stack package, first and second semiconductor chips disposed opposite to each other. The first and second semiconductor chips having bonding bumps are bonded to upper and bottom surfaces of the pattern tape. The bonded chips are then bonded to an upper surface of a substrate. The bond fingers of the substrate are in electrical contact with the bond leads of the pattern tape. Ball lands are formed on the bottom surface of the substrate to which solder balls are attached.

### BACKGROUND OF THE INVENTION

1. Field of the Invention

The present invention relates generally to a semiconductor package, and more particularly to a chip stack package which can prevent a malfunction of a package by having the same signal pathway lengths between semiconductor chips.

2. Description of the Prior Art

As miniaturized electric/electronic products having high capability are required, various technologies for manufacturing high capacity semiconductor modules have been researched and developed. In order to manufacture a high capacity semiconductor module, the capacity of the memory chip is increased by a large integration of the memory chip. Such large integration of the memory chip can be achieved by integrating a larger number of cells in a defined space of the semiconductor chip. However, since the large integration of the memory chip needs an accurate and fine wire width, more advanced technology and much more time are required for developing the largely integrated memory chip. Thus, a chip stack has been proposed as an alternative technology for providing the required high capacity in a semiconductor module.

The chip stack technology involves stacking at least two semiconductor chips vertically. A chip stack package made by such a chip stack technology has the advantage of increasing the capacity, the packaging density, and the efficiency of use of packaging area of the memory.

Hereinafter, a conventional chip stack package will be described with reference to FIG. 1.

Referring to FIG. 1, a substrate 1 is prepared which has a circuit pattern including bond fingers 2a and 2b and a ball land 3, and a cavity formed in a center portion of the substrate 1. A center-pad type first semiconductor chip 4 is attached by adhesive 6 to the substrate 1 in a face-down manner. A bonding pad 5 of the first semiconductor chip 4 is electrically connected with the first bond finger 2a of the substrate 1 by means of a first bonding wire 7. A center-pad type second semiconductor chip 8 is attached by adhesive 10 to the first semiconductor chip 4 in the face-down manner. A bonding pad 9 of the second semiconductor chip 8 is electrically connected with the second bond finger 2b of the substrate 1 by means of a second bonding wire 11. An upper portion of the substrate 1 which includes the first and second semiconductor chips 4 and 8 and the second bonding wire 11, and the cavity of the substrate 1 are molded by using encapsulating resin 12 including epoxy molding compound (EMC). Solder balls 13, which are designed to make electrical contact with an outer circuit, are attached to ball lands 3 on a bottom surface of the substrate 1.

In the conventional chip stack package having the above-mentioned structure, the first semiconductor chip 4 is electrically connected to the substrate 1 by the first bonding wire 7 which is short, while the second semiconductor chip 8 is electrically connected to the substrate 1 by the second bonding wire 11 which is relatively longer than the first bonding wire 7. Thus, the difference in length between the bonding wires 7 and 11 causes the pins of the first and second semiconductor chips 4 and 8 (the pins in each chip performing the same functions) to have difference in RLC values. Such a difference in the RLC values between the pins having the same functions causes introduction of signal delay and signal noise, resulting in malfunction of the package during high-speed operations.

### SUMMARY OF THE INVENTION

Accordingly, the present invention has been developed in order to solve the above-mentioned problems occurring in the prior art, and an object of the present invention is to provide a chip stack package which has the same signal pathway lengths between semiconductor chips.

It is another object of the present invention to provide a chip stack package which has the same signal pathway lengths between semiconductor chips, thereby preventing a malfunction of the package.

In order to accomplish these objects of the present invention, there is provided a chip stack package which comprises: first and second semiconductor chips disposed such that their surfaces having bonding pads are opposite each other; first bumps formed on the bonding pads of the first semiconductor chip, respectively; second bumps formed on the boding pads of the second semiconductor chip, respectively; a pattern tape having an electric connection pattern connecting the first semiconductor chip and the second semiconductor chip through the first and second bumps by flip chip bonding, and bond leads which extend outward from both sides of the pattern tape; a substrate attached the the first semiconductor chip and having bond fingers disposed on an upper surface of the substrate in electric contact with the bond leads of the pattern tape, and the ball lands disposed on a bottom surface of the substrate; and solder balls attached to the ball lands of the substrate respectively.

Here, the first semiconductor chip is disposed in a face-up manner, while the second semiconductor chip is disposed in a face-down manner. The first semiconductor chip is attached to the substrate by adhesive agent. A first encapsulating resin fills in a space between the first semiconductor chip and the pattern tape. A second encapsulating resin fills in a space between the second semiconductor chip and the pattern tape. A third encapsulating resin which covers the upper surface of the substrate including the structure in which the first and second semiconductor chips are bonded to the upper and bottom surfaces of the pattern tape respectively. The first and second semiconductor chips have the same signal pathway lengths due to an existence of the pattern tape.

### BRIEF DESCRIPTION OF THE DRAWINGS

The above and other objects, features, and advantages of the present invention will be more apparent from the following detailed description taken in conjunction with the accompanying drawings, in which:

FIG. 1 is a cross-sectional view showing a conventional chip stack package;

FIG. 2 is a cross-sectional view showing a chip stack package according to an embodiment of the present invention; and

FIG. 3 is a flow diagram for illustrating the process of manufacturing the chip stack package according to an embodiment of the present invention.

### DETAILED DESCRIPTION OF THE PREFERRED EMBODIMENTS

Hereinafter, a preferred embodiment of the present invention will be described with reference to the accompanying drawings.

FIG. 2 is a cross-sectional view showing a chip stack package according to an embodiment of the present invention.

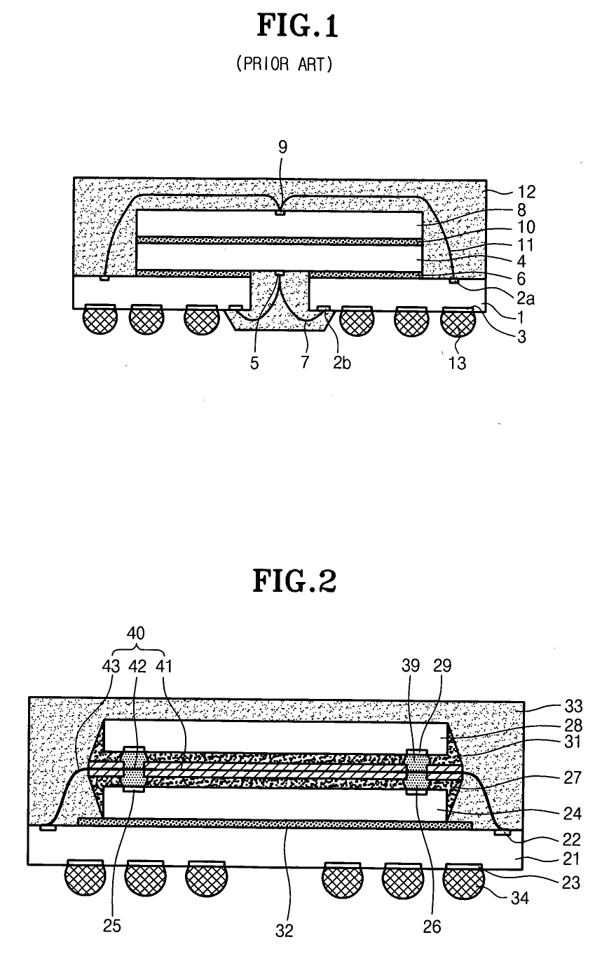

As shown in FIG. 1, an edge-pad type of first semiconductor chip 24 is prepared to have bonding pads 25 disposed on the upper surface of the chip 24 along the vicinity of the edges. The first semiconductor chip 24 includes first bumps 26 having a ball shape and made of conductive material. The first bump 26 is formed on each bonding pad 25 of the first semiconductor chip 24. An electrical connection member, i.e. a pattern tape 40 has a rearranged electrical connection pattern which includes insulation tapes 41, exposed pads 42 having upper and lower surfaces exposed, and bond leads 43 extending outward from both ends thereof, in which the exposed pads 42 and the bond leads 43 are disposed between the insulation tapes 41. In the first semiconductor chip 24, therefore, the bonding pads 25 are in electrical contact with the exposed pads 42 of the pattern tape 40 by the first bumps 26, respectively. As a result, the first semiconductor chip 24 is bonded to the pattern tape 40 in a flip chip bonding manner. The first encapsulating resin 27, such as EMC, fills in a space between the first semiconductor chip 24 and the pattern tape 40 to which the first semiconductor chip 24 is bonded in the flip chip bonding manner, in order to protect the first bumps 26 from exterior stress.

The edge-pad type of second semiconductor chip 28 is prepared similarly to the first semiconductor chip 24, which has bonding pads 29 disposed at the edges on a lower surface thereof. The second semiconductor chip 28 includes second bumps 30 having a ball shape, which are made of conductive material and are respectively formed on each bonding pad 29 of the second semiconductor chip 28. The second semiconductor chip 28 is attached to the pattern tape 40 by means of the second bumps 30 in a face down manner. In the second semiconductor chip 28, the bonding pads 29 have a bottom surface in electrical contact with an upper surface of the exposed pads 42 of the pattern tape 40 by the second bumps 30. The exposed pads 42 of the pattern tape 40 are in electric contact with the bonding pads 25 of the first semiconductor chip 24 by the first bumps 26, respectively. As a result, the second semiconductor chip 28 is bonded to the pattern tape 40 in the flip chip bonding manner. The second encapsulating resin 31, such as EMC, fills in a space between the second semiconductor chip 28 and the pattern tape 40 to which the second semiconductor chip 28 is bonded in the flip chip bonding manner, in order to protect the second bumps 26 from exterior stress.

Here, the first and second semiconductor chips 24 and 28 are in electrical contact with the upper and bottom surfaces of the pattern tape 40 by the first and second bumps 26 and 30, respectively in order to have an equally electric connection pattern, so that the first and second semiconductor chips have the same pathway length for all signals. As described above, since the chip stack package of the present invention is provided with the same pathway length for all the signals from the first and second semiconductor chips 24 and 28, it is possible to effectively prevent a malfunction of the semiconductor chips caused by the difference in the pathway length for all the signals which is a conventional problem.

Next, a substrate 21 is prepared which includes a circuit pattern having bond fingers 22 formed on an upper surface thereof and ball lands 23 disposed on a bottom surface thereof. A structure, in which the first and second semiconductor chips 24 and 28 are respectively bonded to the upper and bottom surfaces of the pattern tape 40 in the flip chip bonding manner, is attached to the substrate 21 in such a manner that the first semiconductor chip 24 is disposed on and adhered to an upper surface of the substrate 21 by adhesive agent 32. The bond leads 43 of the pattern tape 40 are in electric contact with the bond fingers 22 of the substrate 21, respectively. The third encapsulating resin 32, including EMC, seals an upper area of the substrate 21 having the first and second semiconductor chips 24 and 28, the pattern tape 40, and the bond leads 43. Then, solder balls 34 are attached to the ball lands 23 disposed on a bottom surface of the substrate 40, which are used to mount the substrate 21 on an exterior circuit. This results in the accomplishment of the chip stack package according to the present invention.

As described above, in the chip stack package according to the present invention, since the electric contact of the face down type first semiconductor chip 24 with the face up type second semiconductor chip 28 disposed on the substrate is accomplished by the flip chip bonding manner using the pattern tape 40 and the bumps 26 and 30, the signal pathway lengths for the first and second semiconductor chips 24 and 28 can be equal. The chip stack package of the present invention has the same signal pathway length for the first and second semiconductor chips 24 and 28, resulting in the elimination of the problem which may occur due to the difference in the signal pathway lengths for the first and second semiconductor chips 24 and 28. Furthermore, since the chip stack package of the present invention is accomplished by the flip chip bonding manner, it is possible to minimize the signal pathway length, thereby obtaining a more improved characteristic.

With the preferred embodiment of the present invention, on the other hand, the chip stack package has been described in which the edge-pad type of the first and second semiconductor chips are stacked. However, it is understood that the prevent invention can be applied to a chip stack package in which a center-pad type of semiconductor chips are stacked. In this case, the exposed pad of the pattern tape is disposed such that its top and bottom surfaces correspond to the bonding pads of the semiconductor chips respectively.

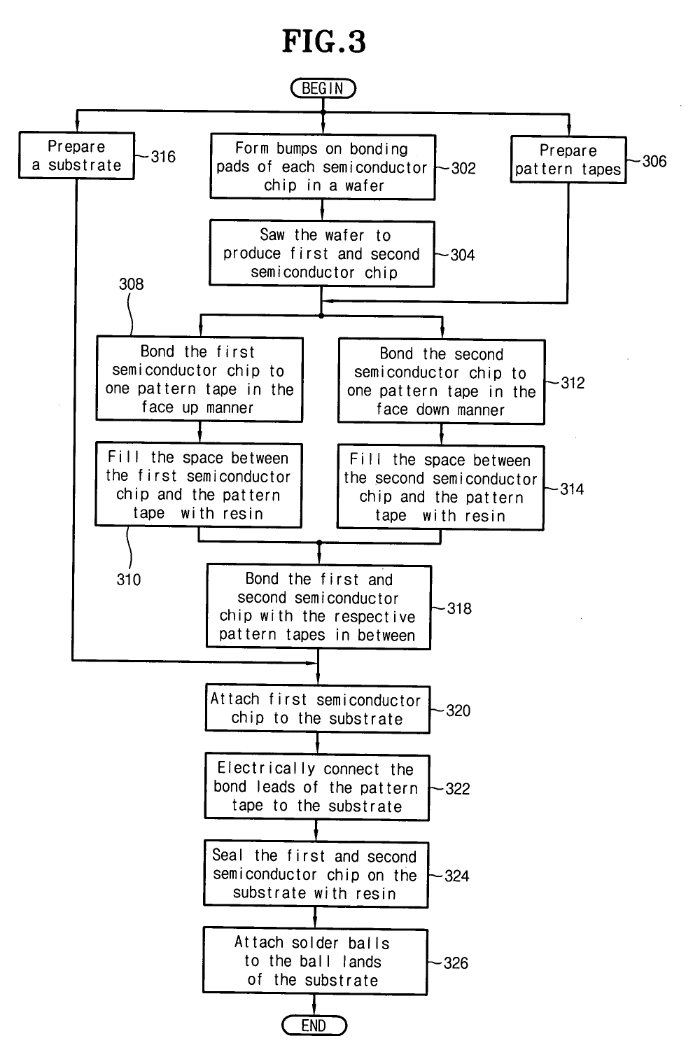

Hereinafter, a process of manufacturing the chip stack package according to an embodiment of the present invention will be described in brief with respect to FIG. 3.

First, referring to step 302, after completion of manufacturing semiconductor device, bumps are formed on bonding pads of each semiconductor chip in a wafer to have a ball shape. Then, a sawing process is performed on the wafer, so that the wafer is divided into the semiconductor chips as in step 304. Thus, the edge-pad type of first and second semiconductor chips can be obtained.

Next in step 306, the pattern tape including pads and bond leads is prepared. Then in step 308, the first semiconductor chip is bonded to the pattern tape in the face-up manner by using the bumps. In turn in step 310, the first encapsulating resin fills in the space between the pattern tape and the first semiconductor chip in order to protect the bumps from the exterior stress.

After the resultant is turned upside down, now referring to step 312, the second semiconductor chip is bonded to the pattern tape in the face-down manner by using the bumps. Then in step 314, the second encapsulating resin fills in the space between the pattern tape and the second semiconductor chip in order to protect the bumps from the exterior stress.

Continuously, the substrate is prepared in step 316 for electrically connecting the pattern tape and the outside, of which the upper surface is coated with adhesive agent. Next in step 318, the structure, in which the first and second semiconductor chips are respectively bonded to the upper and bottom surfaces of the pattern tape, is attached to the substrate such that the first semiconductor chip is adhered to the substrate by the adhesive agent as in step 320.

After the bond fingers of the substrate are in electric contact with the bond leads of the pattern tape respectively in step 322, the third encapsulating resin seals the upper area of the substrate in order to protect the first and second semiconductor chips and the bond leads from exterior force in step 324. Then in step 326, the solder balls are respectively attached to the ball lands disposed on the bottom surface of the substrate so that the first and second semiconductor chips come in electric contact with the exterior circuit, thereby accomplishing the chip stack package according to the present invention.

In the present invention as described above, since the two semiconductor chips are stacked in the flip chip bonding manner using the pattern tape, the semiconductor chips have the same short signal pathway lengths from the bonding pads to the exterior circuit. As a result, it is possible to minimize the possibility of a malfunction of the semiconductor chips caused by a signal delay or noise.

While a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A chip stack package comprising:
first and second semiconductor chips disposed such that their surfaces having bonding pads are opposite to each other;
first bumps formed on the bonding pads of the first semiconductor chip;
second bumps formed on the boding pads of the second semiconductor chip;
a pattern tape having an electrical connection pattern connecting the first semiconductor chip and the second semiconductor chip through the first and second bumps by flip chip bonding, wherein bond leads extend outward from both sides of the pattern tape;
a substrate attached the first semiconductor chip and having bond fingers disposed on an upper surface of the substrate in electrical contact with the bond leads of the pattern tape, wherein ball lands are disposed on a bottom surface of the substrate; and
solder balls attached to the ball lands of the substrate.

2. The chip stack package as claimed in claim 1, wherein the first semiconductor chip is disposed in a face-up manner with the first bumps formed in the upward direction toward the second semiconductor chip, while the second semiconductor chip is disposed in a face-down manner with the second bumps formed in the downward direction toward the fist semiconductor chip.

3. The chip stack package as claimed in claim 2, wherein the first semiconductor chip arranged in the face-up manner is attached to the substrate.

4. The chip stack package as claimed in claim 3, wherein the first semiconductor chip is attached to the upper surface of the substrate by adhesive agent.

5. The chip stack package as claimed in claim 1, further comprising a first encapsulating resin fills in a space between the first semiconductor chip and the pattern tape.

6. The chip stack package as claimed in claim 1, further comprising a second encapsulating resin fills in a space between the second semiconductor chip and the pattern tape.

7. The chip stack package as claimed in claim 1, further comprising a third encapsulating resin which covers the upper surface of the substrate including the structure in which the first and second semiconductor chips are bonded to the upper and bottom surfaces of the pattern tape respectively.

8. The chip stack package as claimed in claim 1, wherein the first and second semiconductor chips have the same signal pathway lengths due to an existence of the pattern tape.
